(19) United States
(12) Patent Application Publication
(10) Pub. No.: US 2026/0245774 A1
(43) Pub. Date: Aug. 20, 2026

(54) SHIELDED FLEXIBLE RIBBON CABLE

(71) Applicant: NEXANS, Courbevoie (FR)

(72) Inventors: Armin HOEHNE, STÖRNSTEIN (DE); Ulrich DOELLINGER, FLOSS (DE); Helmut STEINBERG, STÖRNSTEIN (DE); Frank SCHRÖER, WEIDEN (DE)

(21) Appl. No.: 19/019,976

(22) Filed: Jan. 14, 2025

(30) Foreign Application Priority Data
Jan. 15, 2024 (DE) 102024101089.4

(51) Int. Cl. H01B 13/22; H01B 7/08; H01B 11/08; H01B 11/10

(52) U.S. Cl. CPC H01B 13/22; H01B 7/0838; H01B 7/0861; H01B 11/08; H01B 11/1008

(57) ABSTRACT

A method for producing a shielded ribbon cable for higher powers is provided. The ribbon cable has, in addition to wires for direct or alternating currents arranged in a plurality of layers located one above the other, uppermost and bottommost shielding surfaces as well as shielding wires, running laterally, in the planes.

### RELATED APPLICATION

This application claims the benefit of priority from German Patent Application No. 10 2024 101 089.4 filed on Jan. 15, 2024, the entirety of which is incorporated by reference.

### FIELD

The present invention relates to flexible ribbon cables, that is to say cables which have one or more conductors applied to a flexible carrier of insulating material. Such cables are also known by the names foil cables, flat flex cables or flexible flat cables (FFC). These names are used synonymously hereinbelow.

### BACKGROUND

Foil cables are used in particular where the installation space for other types of cable is not sufficient, especially when a large number of wires are guided parallel to one end of the cable.

For data cables via which data are guided with high transfer rates, and which are to be shielded with respect to electromagnetic interference, corresponding shields must be provided, which are connected at one end or at both ends of a cable to a reference potential, generally to an earth or ground potential.

In known shielded FFCs, after lamination of the actual FFC, a shielding layer, for example in the form of a metallized plastics film, is wound around the FFC. This subsequent application is comparatively complex and requires additional production steps.

Published patent application US 2021/0166836 A1 discloses a shielded FFC in which two signal wires running parallel to one another are arranged between two shielding wires running parallel to the signal wires. The shielding wires have exposed regions along the longitudinal extent of the FFC. On the upper and lower sides of the FFC there are arranged shielding surfaces, which are in each case electrically conductively connected to exposed regions of the shielding wires.

The known FFCs have only a single layer for signal wires, so that the power which can be transmitted thereby is limited even in the case of comparatively wide conductors. In particular in applications in which large currents flow in a high-frequency pulsed manner, it has not hitherto been possible to utilize the advantages of shielded FFCs.

### OBJECTS AND SUMMARY

Accordingly, an object of the present invention is to provide a method for producing a shielded FFC for higher powers.

This object is achieved by the method indicated in claim 1. Further embodiments and further developments of the method are indicated in the dependent claims.

A method for producing a shielded flexible ribbon cable having a first length and a first width according to a first aspect of the invention comprises providing at least two electrically insulating carrier layers of equal length and width. At least one conductor has been applied to a surface of each of the at least two carrier layers. The method further comprises placing the at least two carrier layers with the conductors applied thereto one above the other in a congruent manner and mechanically connecting them. The mechanical connection is designed to prevent at least separation or delamination of the layers. A slight displacement of the layers relative to one another can be possible or even desirable. The mechanical connection of the layers can be effected by adhesive bonding, by partial melting of the layers, or by structures that engage into one another in a suitable form. The method additionally comprises applying an insulating layer to the at least one conductor of the uppermost carrier layer, wherein the insulating layer extends over a second length, which is shorter than the first length, and wherein the ends of the insulating layer are spaced apart from the respective ends of the carrier layer, so that the at least one conductor is accessible at the respective ends for electrical contacting. The method further comprises applying a closed first shielding surface to the uppermost insulating layer. The first shielding surface extends in the direction of the width of the ribbon cable at least over all the conductors and in the direction of the length of the ribbon cable over a third length, which is shorter than the first length. Preferably, the third length is as long as the second length, or only slightly shorter. In an analogous manner, a closed second shielding surface is applied beneath the bottommost carrier layer. The second shielding surface extends in the direction of the width of the ribbon cable at least over all the conductors and in the direction of the length of the ribbon cable over a fourth length. The fourth length can correspond to the third length or be shorter or longer than the third length, but it is not longer than the first length. The first shielding surface and the insulating layer located beneath it are so oriented relative to the carrier layers that conductors are electrically contactable at both ends of the carrier layers. Alternatively, the first shielding surface and the insulating layer located beneath it are so oriented relative to the carrier layers that one or more conductors are electrically contactable at one end of the carrier layers, and the second shielding surface is so oriented relative to the other end of the carrier layers that one or more conductors are electrically contactable at the other end of the carrier layers. In both alternatives, it is thus ensured that the one or more conductors of the at least two carrier layers are not simultaneously covered by both shielding surfaces at either end of the ribbon cable, and an electrical connection is possible.

In one embodiment of the method, one or more electrically insulating carrier layers are provided, wherein at least one conductor has been applied to two opposite surfaces of at least one of the carrier layers. In this embodiment, the method additionally comprises applying an insulating layer between those carrier layers which have mutually opposite conductors, or between the bottommost carrier layer and the shielding surface located at the bottom, provided this bottommost carrier layer has conductors facing the shielding surface. The application of an insulating layer can be omitted if it is ensured, by the guidance of the conductors, that, in the stacked state, only conductors that conduct equal potentials and/or identical currents with the same flow direction can touch one another.

In one or more embodiments, the method additionally comprises electrically connecting the first and the second shielding surfaces at least at one end of the ribbon cable.

In one or more embodiments of the method, one or more electrically insulating carrier layers are provided, wherein on at least one of the carrier layers there are provided at least three conductors, at least one of which runs close to and along one of the long edges of the carrier layer. Running close to the edge can include a distance of a few millimetres, wherein the distance is preferably less than 1 mm. In this embodiment, the method additionally comprises electrically contacting the first and/or the second shielding surface with at least one of the at least one conductor running close to the long edge. The electrical connection is effected at least at one end of the shielding surface but may also be effected at both ends, and/or at one or more arbitrary locations.

As well as being used as data cables, the FFCs produced by the method described above can also be used as shielded cables for supplying power to electrical or electronic components or assemblies. To this end, the width of the FFC can be increased and a plurality of conductor layers can be stacked one above the other. It is here possible, for example in the case of “two-core” FFCs, by the suitable allocation of layers, to achieve at least partial elimination of electromagnetic radiation as a result of the current flow. This can be the case, for example, when the outgoing and return cables of an FFC power supply cable are in each case arranged alternately one above the other. Thus, electromagnetic radiation can be reduced even in the case of power supply cables via which high-frequency connected currents flow.

In order to improve the shielding effect, in addition to connecting the outer shielding layers only at the respective ends, further connections of the shielding layers and optionally of the drain or shielding wires running at the edge of the carrier layer can also be provided.

### BRIEF DESCRIPTION OF THE DRAWING

In the following section, the invention will be explained in greater detail with reference to the drawing, in which

FIG. 1 shows an exploded drawing of a first embodiment of a flexible ribbon cable according to the invention,

FIG. 2 shows an exploded drawing of a second embodiment of a flexible ribbon cable according to the invention,

FIG. 3 shows an exploded drawing of a third embodiment of a flexible ribbon cable according to the invention, and

FIG. 4 shows an exploded drawing of a fourth embodiment of a flexible ribbon cable according to the invention.

In the figures, identical or similar elements may be referenced with the same reference signs.

### DESCRIPTION OF EXEMPLARY EMBODIMENTS

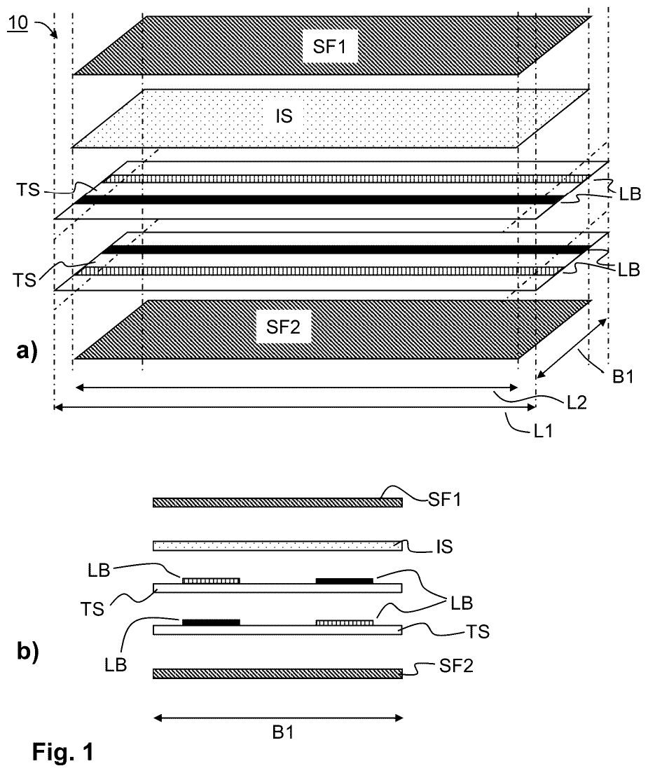

FIG. 1 shows an exploded drawing of a first embodiment of a flexible ribbon cable 10 according to the invention. FIG. 1 a) shows a perspective representation and FIG. 1 b) shows a sectional representation. Two carrier layers TS each with conductors LB applied to one side are arranged one above the other. The conductors LB are shown merely by way of example and may be wider than shown in the figure. The conductors LB in the figure are provided, for example, for a direct voltage power supply and comprise a conductor for the positive supply voltage, here shown in black, and a conductor for the negative supply voltage or ground, here shown with vertical hatching. The conductors LB can in each case be so arranged that the magnetic fields caused by the flowing current at least partially cancel each other out. For this purpose, in each case a black conductor and a vertically hatched conductor are here arranged directly one on top of the other. Above and below the two carrier layers TS there is arranged in each case a continuous shielding surface SF1 and SF2. An insulating layer IS arranged between the upper carrier layer and the upper shielding surface SF1 prevents an electrical short circuit between the conductors LB and the upper shielding surface SF1. The dimensions of the insulating layer IS are at least sufficiently great that the conductors LB are covered, but without impairing the possibility of electrical contacting of the conductors LB. Likewise, the dimensions of the shielding surfaces SF1 and SF2 are so chosen that a connecting region for the conductors remains accessible LB at the ends of the carrier layers TS, but an electrical short circuit with the conductors LB is avoided. This can be achieved, for example, if the shielding surfaces SF1 and SF2 are not larger than the insulating layer. In this and the following figures, the different dimensions of individual layers or surfaces are illustrated by dot-and-dash reference lines.

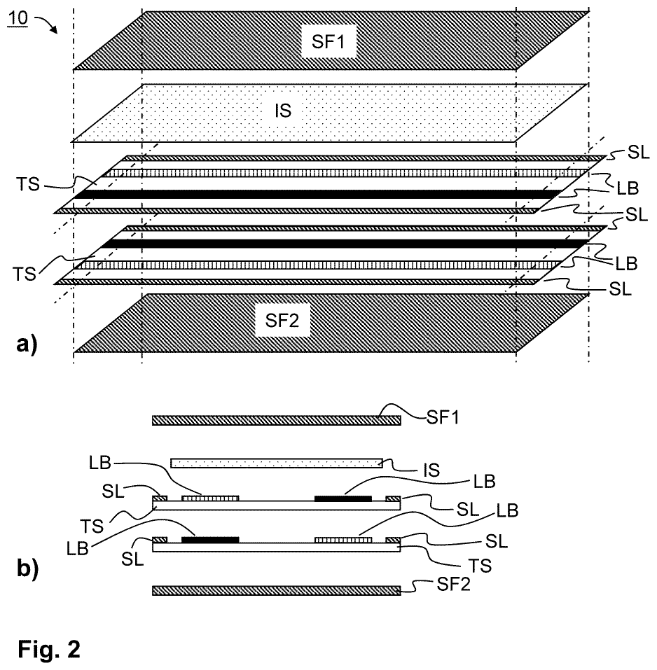

FIG. 2 shows an exploded drawing of a second embodiment of a flexible ribbon cable 10 according to the invention, again in a perspective representation in FIG. 2 a) and in a sectional representation in FIG. 2 b). The second embodiment corresponds substantially to that of FIG. 1. In contrast to the embodiment described above, shielding wires SL are provided at the outer edges of the carrier layers and can be electrically connected to the shielding surfaces SF1, SF2. The connection can be made in the connecting region, that is to say at the ends of the ribbon cable, or also by means of feedthroughs or direct electrical contact at any desired location. For this purpose, the insulating layer IS, as shown in the figure, can have a smaller width than the carrier layers, so that direct electrical contact between the shielding wire SL and the shielding surface SF is possible.

It should be noted that the thicknesses of the different elements, unlike in the schematic representations of the drawing, may be different in all the embodiments. Thus, the shielding wires, for example, may be thicker than the conductors LB, in order thus to compensate to a certain extent for the thickness of the insulating layer IS. The insulating layer IS may also be so designed that, after application thereof, a substantially planar surface is obtained.

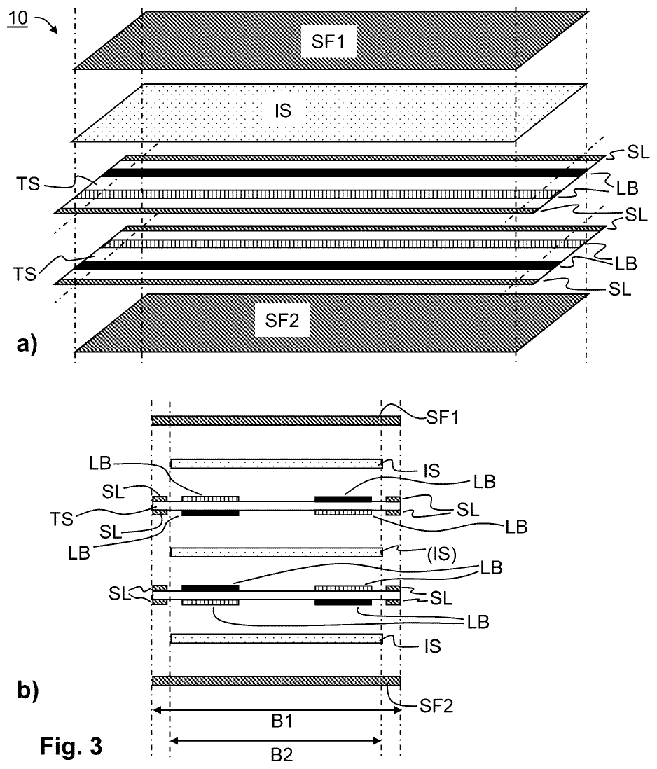

FIG. 3 shows an exploded drawing of a third embodiment of a flexible ribbon cable 10 according to the invention, as in FIGS. 1 and 2 in a perspective representation in FIG. 3 a) and in a sectional representation in FIG. 3 b). In this embodiment, the conductors LB are for the most part located such that the magnetic fields caused by the flowing current at least partially cancel each other out, as described under FIG. 1. In this embodiment, conductors LB have for this purpose been applied to both surfaces of the carrier layers TS. The currents in the conductors LB located directly above one another preferably flow in opposite flow directions and their magnitudes are preferably equal. Insulating layers IS are provided in each case between the two carrier layers TS and between the shielding surfaces SF1, SF2 and the carrier layer adjacent thereto, in order to prevent electrical short circuits. The insulating layer IS between the two carrier layers TS may optionally be omitted if permitted by the guidance of the conductors LB, for example if conductors LB with the same currents and flow directions lie one on top of another. In the figure, shielding wires SL are again provided on the long sides of the ribbon cable 10. These can be applied to both sides of the carrier layers TS, and the insulating layers IS can have a smaller width B2 than the width B1 of the carrier layers. As a result, the shielding wires SL and the shielding surfaces SF1, SF2 can come into direct electrical contact with one another and improve the shielding effect and also simplify connection.

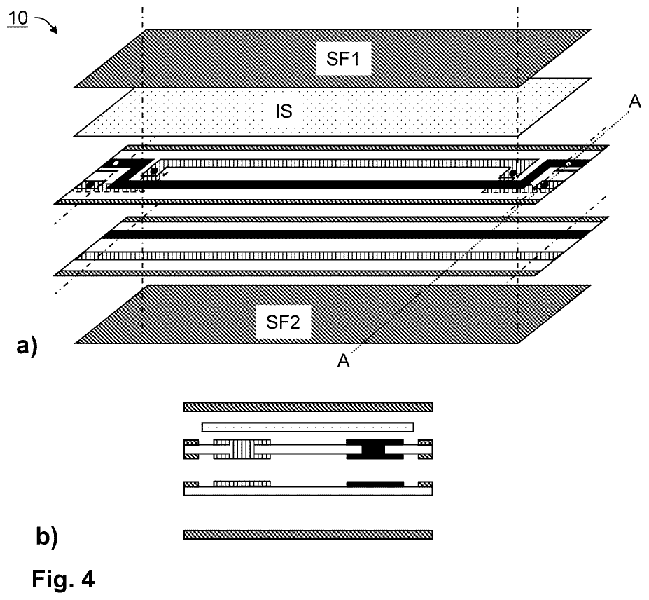

In all embodiments of the ribbon cable, the cable guidance may be such that the connection of cables of adjacent carrier layers that conduct the same potentials or signals is simplified with corresponding connections. An example of an embodiment is shown in FIG. 4.

FIG. 4 shows an exploded drawing of a fourth embodiment of a flexible ribbon cable 10 according to the invention. In FIG. 4 a), a perspective representation is again shown, while FIG. 4 b) shows a sectional representation for the section through a plane in which the dotted straight line A-A runs. As can readily be seen in FIG. 4 a), by means of a suitable side change of the conductors on one of the carrier layers, the magnetic field generated by the current flow is counteracted over a larger distance, while the connections at the ends of the carrier layers are appropriately located relative to one another. The individual elements have not been designated in the figure; reference may be made to the figures described above.

### LIST OF REFERENCE SIGNS

10 Ribbon cable
Bx Width
Lx Length
TS Carrier layer
LB Conductor
IS Insulating layer
SFx Shielding surface
SL Shielding wire

1. A method for producing a shielded flexible ribbon cable having a first length and a first width, comprising:
providing at least two electrically insulating carrier layers of equal length and width, wherein at least one conductor has been applied to a surface of each of the at least two carrier layers, and
placing the at least two carrier layers with the conductors applied thereto one above the other in a congruent manner and mechanically connecting them,
applying an insulating layer to the at least one conductor of the uppermost carrier layer, wherein the insulating layer extends over a second length, which is shorter than the first length, and wherein the ends of the insulating layer are spaced apart from the respective ends of the carrier layer, so that the at least one conductor is accessible at the respective ends for electrical contacting,
wherein the method further comprises:
applying a closed first shielding surface to the uppermost insulating layer, which first shielding surface extends in the direction of the width of the ribbon cable at least over all the conductors and which first shielding surface extends in the direction of the length of the ribbon cable over a third length, which is shorter than the first length,
applying a closed second shielding surface beneath the bottommost carrier layer, which second shielding surface extends in the direction of the width of the ribbon cable at least over all the conductors and which extends in the direction of the length of the ribbon cable over a fourth length, which is not longer than the first length,
wherein either the first shielding surface and the insulating layer located beneath it are so oriented relative to the carrier layers that conductors are electrically contactable at both ends of the carrier layers, or wherein the first shielding surface and the insulating surface located beneath it are so oriented relative to the carrier layers that one or more conductors are electrically contactable at one end of the carrier layers, and the second shielding surface is so oriented relative to the other end of the carrier layers that one or more conductors are electrically contactable at the other end of the carrier layers, so that the one or more conductors of the at least two carrier layers are not simultaneously covered by both shielding surfaces at either end of the ribbon cable.

2. The method according to claim 1, additionally comprising:
electrically connecting the first and the second shielding surfaces at least at one end of the ribbon cable.

3. The method according to claim 1, wherein at least three conductors are provided on the at least one carrier layer, and wherein the method additionally comprises:
electrically contacting the first and/or the second shielding surface with at least one of the outermost conductors at least at one end of the respective shielding surface.

4. A shielded ribbon cable produced by the method of one or more of claim 1.
